(19) United States
(12) Patent Application Publication
(10) Pub. No.: US 2012/0241865 A1
(43) Pub. Date: Sep. 27, 2012

(54) INTEGRATED CIRCUIT STRUCTURE

(75) Inventors: Vassil Antonov, Boise, ID (US); Vishwanath Bhat, Boise, ID (US); Noel Rocklein, Boise, ID (US); Chris Carlson, Nampa, ID (US)

(73) Assignee: NANYA TECHNOLOGY CORPORATION, Kueishan (TW)

(21) Appl. No.: 13/052,735

(22) Filed: Mar. 21, 2011

(51) Int. Cl. H01L 29/78; H01L 29/92

(52) U.S. Cl. 257/368; 257/532; 257/E29.255; 257/E29.342

(57) ABSTRACT

One aspect of the present invention provides an integrated circuit structure including a semiconductor substrate, a bottom dielectric layer positioned on the substrate, at least two capping dielectric layers positioned on the bottom dielectric layer, and a metal layer positioned on the at least two capping dielectric layers, wherein one of the two capping dielectric layers is an aluminum oxide layer, and the other is a silicon oxide layer. Another aspect of the present invention provides an integrated circuit structure including a bottom electrode, a bottom dielectric layer positioned on the bottom electrode, at least two capping dielectric layers positioned on the bottom dielectric layer, and a top electrode positioned on the at least two capping dielectric layers, wherein one of the two capping dielectric layers is an aluminum oxide layer, and the other is a silicon oxide layer.

### BACKGROUND OF THE INVENTION

(A) Field of the Invention

The present invention relates to an integrated circuit, and more particularly, to an integrated circuit structure having a plurality of capping dielectric layers on a bottom dielectric layer.

(B) Description of the Related Art

DRAM is a widely used integrated circuit technology. As the semiconductor industry advances, there is increasing demand for DRAM with greater storage capacity. The memory cell of a DRAM consists of a metal-oxide-semiconductor (MOS) transistor and a capacitor electrically connected to each other. The capacitor functions to store the electric charge representing data, and high capacitance is necessary to prevent the data from being lost due to discharge. The method to increase electric charge storing capacity of the capacitor can be achieved by increasing the dielectric constant of the dielectric material and reducing the thickness of the dielectric material used in the capacitor, or by increasing the surface area of the capacitor. However, as semiconductor technology proceeds into sub-micron and deep sub-micron scales, the traditional fabrication process for preparing the capacitor is no longer applicable. Consequently, researchers are currently seeking to develop dielectric material with a greater dielectric constant and to increase surface area of the capacitor so as to increase the capacitance.

In addition, as the scale of MOS transistors is reduced, the ultra thin gate oxide dielectric layer that forms portions of the devices may exhibit undesirable current leakage. In order to minimize current leakage while maintaining high drive current, low equivalent oxide thickness (EOT) may be achieved by using thicker films.

The constant reduction of electronic device dimensions with each new generation necessitates the continued improvement in the properties of these devices, so that they can meet their performance requirements at the reduced dimensions. In the context of metal-insulator-metal capacitors, such requirements determine the necessary levels of cell capacitance and dielectric leakage current. It is well known that the interface of the capacitor dielectric with the metal electrodes plays a crucial role in capacitor performance, and particular care must be taken in the design of such interfaces.

### SUMMARY OF THE INVENTION

One aspect of the present invention provides an integrated circuit structure having a plurality of capping dielectric layers on a bottom dielectric layer.

One aspect of the present invention provides an integrated circuit structure, comprising a semiconductor substrate, a bottom dielectric layer positioned on the substrate, at least two capping dielectric layers positioned on the bottom dielectric layer, and a metal layer positioned on the at least two capping dielectric layers, wherein one of the two capping dielectric layers is an aluminum oxide layer, and the other is a silicon oxide layer.

Another aspect of the present invention provides an integrated circuit structure comprising a bottom electrode, a bottom dielectric layer positioned on the bottom electrode, at least two capping dielectric layers positioned on the bottom dielectric layer, and a top electrode positioned on the at least two capping dielectric layers, wherein one of the two capping dielectric layers is an aluminum oxide layer, and the other is a silicon oxide layer.

The foregoing has outlined rather broadly the features of the present invention in order that the detailed description of the invention that follows may be better understood. Additional features of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes as those of the present invention. It should also be realized by those skilled in the art that such equivalent constructions do not depart from the spirit and scope of the invention as set forth in the appended claims.

### BRIEF DESCRIPTION OF THE DRAWINGS

The objectives of the present invention will become apparent upon reading the following description and upon reference to the accompanying drawings in which:

FIG. 1 is a cross-sectional view of an integrated circuit structure according to one embodiment of the present invention;

FIG. 2 is a cross-sectional view of an integrated circuit structure according to one embodiment of the present invention;

FIG. 3 is a cross-sectional view of an integrated circuit structure according to one embodiment of the present invention;

FIG. 4 is a cross-sectional view of an integrated circuit structure according to one embodiment of the present invention;

FIG. 5 is a chart showing the capacitance variation of six capacitors with different laminate capping layers serving as the insulator;

FIG. 6 is a chart showing the capacitance-frequency slope variation of the six capacitors with different laminate capping layers serving as the insulator; and

FIG. 7 is a chart showing the leakage variation of the six capacitors with different laminate capping layers serving as the insulator.

### DETAILED DESCRIPTION OF THE INVENTION

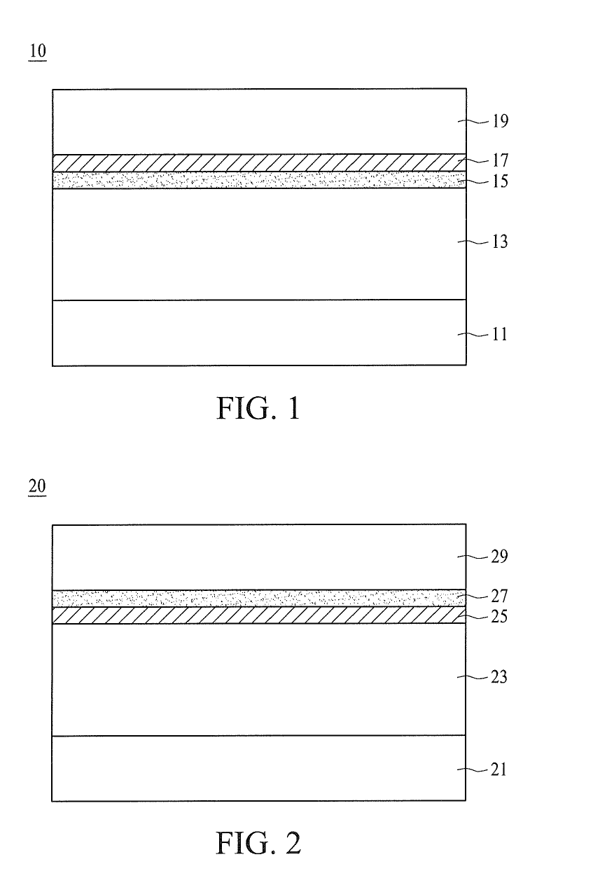

FIG. 1 is a cross-sectional view of an integrated circuit structure 10 according to one embodiment of the present invention. In one embodiment of the present invention, the integrated circuit structure 10 comprises a semiconductor substrate 11, a bottom dielectric layer 13 positioned on the semiconductor substrate 11, at least two capping dielectric layers 15, 17 positioned on the bottom dielectric layer 11, and a metal layer 19 positioned on the at least two capping dielectric layers 15, 17. In one embodiment of the present invention, the semiconductor substrate 11 is a silicon substrate, the metal layer 19 is configured to function as a gate of a metal-oxide-semiconductor transistor, and the bottom dielectric layer 13 and the at least two capping dielectric layers 15, 17 are configured to function as a gate dielectric of the metal-oxide-semiconductor transistor. In one embodiment of the present invention, the bottom dielectric layer 13 is a metal oxide layer, and the metal is selected from the group consisting of hafnium, zirconium, and mixtures thereof.

In one embodiment of the present invention, one of the two capping dielectric layers 15, 17 is an aluminum oxide layer, and the other is a silicon oxide layer. In one embodiment of the present invention, the capping dielectric layer 15 positioned on the bottom dielectric layer 13 is an aluminum oxide layer, and the capping dielectric layer 17 positioned on the aluminum oxide layer 15 is a silicon oxide layer. In one embodiment of the present invention, the aluminum oxide layer 15 and the silicon oxide layer 17 are prepared by the atomic layer deposition (ALD) process, the thickness of the aluminum oxide layer 15 is between 1 and 5 angstroms, and the thickness of the silicon oxide layer 17 is between 1 and 5 angstroms. In one embodiment of the present invention, the thickness of the silicon oxide layer 17 is substantially the same as that of the aluminum oxide layer 15. In one embodiment of the present invention, the thickness of the bottom dielectric layer 13 is between 40 and 200 angstroms.

FIG. 2 is a cross-sectional view of an integrated circuit structure 20 according to one embodiment of the present invention. In one embodiment of the present invention, the integrated circuit structure 20 comprises a semiconductor substrate 21, a bottom dielectric layer 23 positioned on the semiconductor substrate 21, at least two capping dielectric layers 25, 27 positioned on the bottom dielectric layer 21, and a metal layer 29 positioned on the at least two capping dielectric layers 25, 27. In one embodiment of the present invention, the semiconductor substrate 21 is a silicon substrate, the metal layer 29 is configured to function as a gate of a metal-oxide-semiconductor transistor, and the bottom dielectric layer 23 and the at least two capping dielectric layers 25, 27 are configured to function as a gate dielectric of the metal-oxide-semiconductor transistor. In one embodiment of the present invention, the bottom dielectric layer 23 is a metal oxide layer, and the metal is selected from the group consisting of hafnium, zirconium, and mixtures thereof.

In one embodiment of the present invention, one of the two capping dielectric layers 25, 27 is an aluminum oxide layer, and the other is a silicon oxide layer. In one embodiment of the present invention, the capping dielectric layer 25 positioned on the bottom dielectric layer 23 is a silicon oxide layer, and the capping dielectric layer 27 positioned on the silicon oxide layer 25 is an aluminum oxide layer. In one embodiment of the present invention, the silicon oxide layer 25 and the aluminum oxide layer 27 are prepared by the atomic layer deposition process, the thickness of the silicon oxide layer 25 is between 1 and 5 angstroms, and the thickness of the aluminum oxide layer 27 is between 1 and 5 angstroms. In one embodiment of the present invention, the thickness of the aluminum oxide layer 27 is substantially the same as that of the silicon oxide layer 25. In one embodiment of the present invention, the thickness of the bottom dielectric layer 23 is between 40 and 200 angstroms.

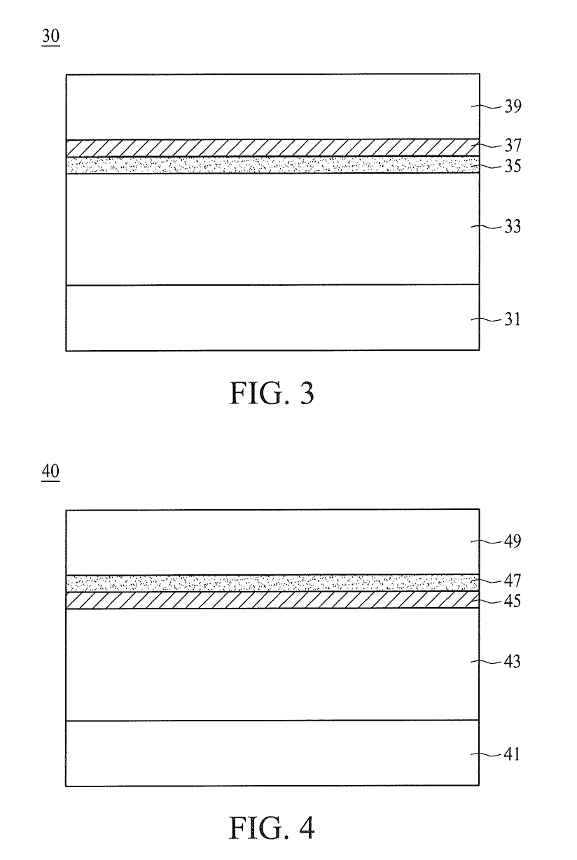

FIG. 3 is a cross-sectional view of an integrated circuit structure 30 according to one embodiment of the present invention. In one embodiment of the present invention, the integrated circuit structure 30 comprises a bottom electrode 31, a bottom dielectric layer 33 positioned on the bottom electrode 31, at least two capping dielectric layers 35, 37 positioned on the bottom dielectric layer 33, and a top electrode 39 positioned on the at least two capping dielectric layers 35, 37. In one embodiment of the present invention, the bottom dielectric layer 33 and the at least two capping dielectric layers 35, 37 are configured to function as an insulator of a metal-insulator-metal (MIM) capacitor, and the bottom electrode 31 and the top electrode 39 are configured to function as the two metal electrodes of the MIM capacitor. In one embodiment of the present invention, the bottom dielectric layer 33 is a metal oxide layer, and the metal is selected from the group consisting of hafnium, zirconium, and mixtures thereof.

In one embodiment of the present invention, one of the two capping dielectric layers 35, 37 is an aluminum oxide layer, and the other is a silicon oxide layer. In one embodiment of the present invention, the capping dielectric layer 35 positioned on the bottom dielectric layer 33 is an aluminum oxide layer, and the capping dielectric layer 37 positioned on the aluminum oxide layer 35 is a silicon oxide layer. In one embodiment of the present invention, the aluminum oxide layer 35 and the silicon oxide layer 37 are prepared by the atomic layer deposition process, the thickness of the aluminum oxide layer 35 is between 1 and 5 angstroms, and the thickness of the silicon oxide layer 37 is between 1 and 5 angstroms. In one embodiment of the present invention, the thickness of the silicon oxide layer 37 is substantially the same as that of the aluminum oxide layer 35. In one embodiment of the present invention, the thickness of the bottom dielectric layer 33 is between 40 and 200 angstroms.

FIG. 4 is a cross-sectional view of an integrated circuit structure 40 according to one embodiment of the present invention. In one embodiment of the present invention, the integrated circuit structure 40 comprises a bottom electrode 41, a bottom dielectric layer 43 positioned on the bottom electrode 41, at least two capping dielectric layers 45, 47 positioned on the bottom dielectric layer 43, and a top electrode 49 positioned on the at least two capping dielectric layers 45, 47. In one embodiment of the present invention, the bottom dielectric layer 43 and the at least two capping dielectric layers 45, 47 are configured to function as an insulator of a metal-insulator-metal (MIM) capacitor, and the bottom electrode 41 and the top electrode 49 are configured to function as the two metal electrodes of the MIM capacitor. In one embodiment of the present invention, the bottom dielectric layer 43 is a metal oxide layer, and the metal is selected from the group consisting of hafnium, zirconium, and mixtures thereof.

In one embodiment of the present invention, one of the two capping dielectric layers 45, 47 is an aluminum oxide layer, and the other is a silicon oxide layer. In one embodiment of the present invention, the capping dielectric layer 45 positioned on the bottom dielectric layer 43 is a silicon oxide layer, and the capping dielectric layer 47 positioned on the silicon oxide layer 45 is an aluminum oxide layer. In one embodiment of the present invention, the silicon oxide layer 45 and the aluminum oxide layer 47 are prepared by the atomic layer deposition process, the thickness of the silicon oxide layer 45 is between 1 and 5 angstroms, and the thickness of the aluminum oxide layer 47 is between 1 and 5 angstroms. In one embodiment of the present invention, the thickness of the aluminum oxide layer 47 is substantially the same as that of the silicon oxide layer 45. In one embodiment of the present invention, the thickness of the bottom dielectric layer 43 is between 40 and 400 angstroms.

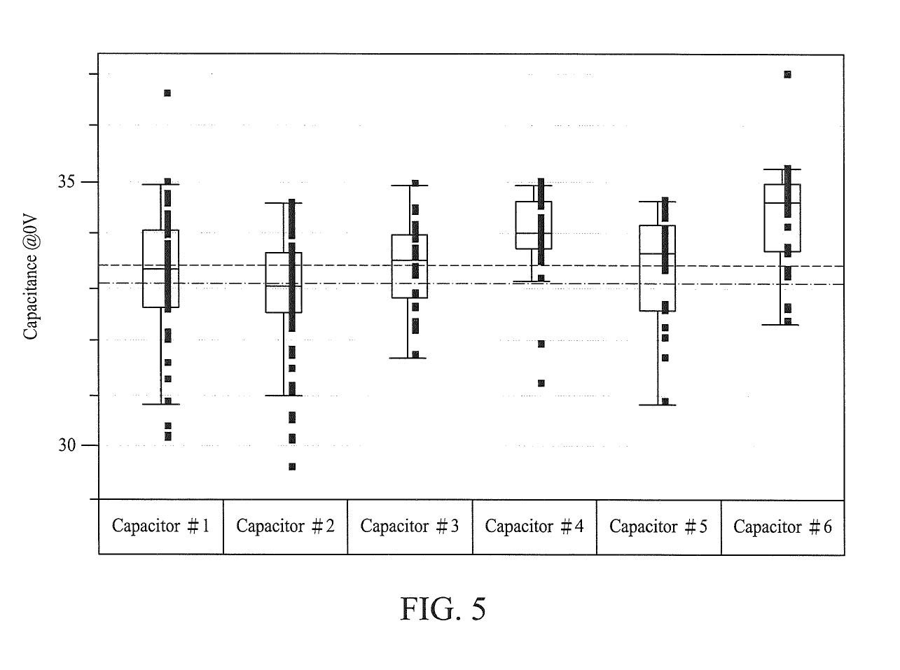

FIG. 5 is a chart showing the capacitance variation of six capacitors with different laminate capping layers serving as the insulator as shown below:

| | Insulator | | |
|---|---|---|---|
| Capacitor | Bottom dielectric | Capping dielectric 1 | Capping dielectric 2 |
| 1 | ZrOx (100 Å) | AlOx (2 Å) | X |
| 2 | ZrOx (100 Å) | SiOx (2 Å) | X |
| 3 | ZrOx (100 Å) | AlOx (1 Å) | SiOx (1 Å) |
| 4 | ZrOx (100 Å) | AlOx (2 Å) | SiOx (2 Å) |
| 5 | ZrOx (100 Å) | SiOx (1 Å) | AlOx (1 Å) |
| 6 | ZrOx (100 Å) | SiOx (2 Å) | AlOx (2 Å) |

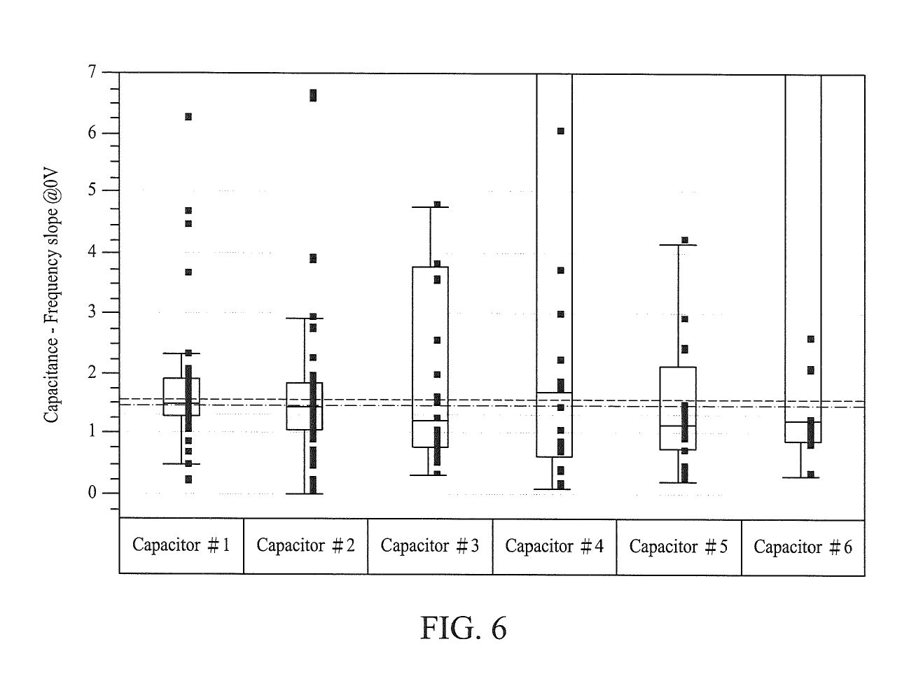

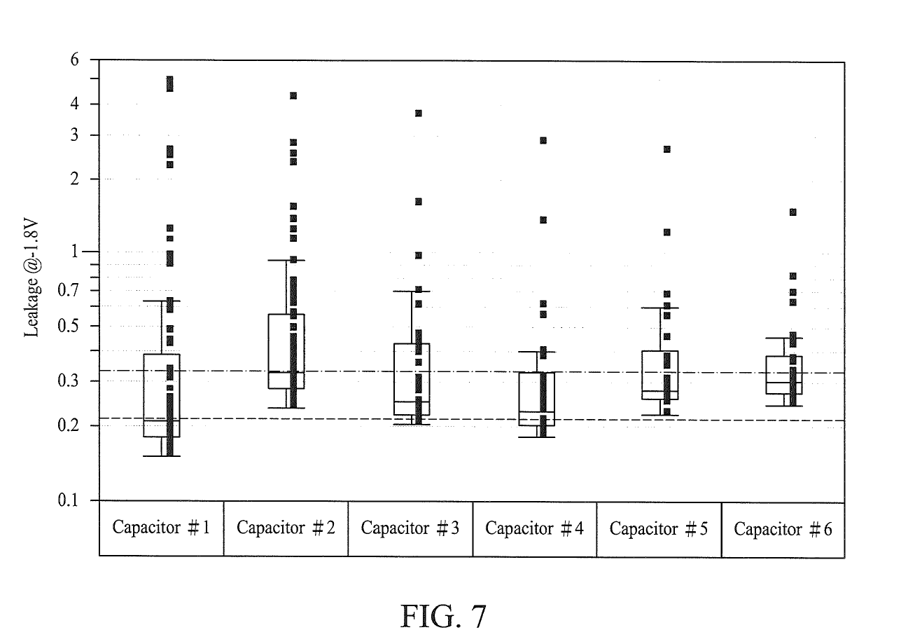

FIG. 6 is a chart showing the capacitance-frequency slope variation of the six capacitors with different laminate capping layers serving as the insulator, and FIG. 7 is a chart showing the leakage variation of the six capacitors with different laminate capping layers serving as the insulator.

Referring to FIG. 5, the capacitors #3, #4, #5, and #6 with AlOx/SiOx laminate capping layers show higher capacitance than the capacitors #1 and #2 with single capping layer. Referring to FIG. 6, the capacitors #3, #5, and #6 with AlOx/SiOx laminate capping layers show lower capacitance-frequency slope than the capacitors #1 and #2 with single capping layer. Referring to FIG. 7, the capacitors #3, #4, #5, and #6 with AlOx/SiOx laminate capping layers show a level of leakage that is substantially the same as that of the capacitors #1 and #2 with single capping layer. In particular, the highest capacitance is seen with the thickest laminate capping layers (the capacitors #5 and #6), while the leakage median of the capacitors #5 and #6 at −1.8V is lower than the leakage of the capacitor #2 with single capping layer (SiOx). Depending on performance requirements, the laminate capping layers can be optimized for highest capacitance (capacitor #6), lowest leakage (capacitor #4), or lowest capacitance-frequency slope (capacitor #5).

Although the present invention and its objectives have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An integrated circuit structure, comprising:
a semiconductor substrate;
a bottom dielectric layer positioned on the substrate;
at least two capping dielectric layers positioned on the bottom dielectric layer, wherein one of the two capping dielectric layers is an aluminum oxide layer, and the other is a silicon oxide layer; and
a metal layer positioned on the at least two capping dielectric layers.

2. The integrated circuit structure of claim 1, wherein the bottom dielectric layer comprises a metal oxide layer, and the metal is selected from the group consisting of hafnium, zirconium, and mixtures thereof.

3. The integrated circuit structure of claim 1, wherein the at least two capping dielectric layers comprise:
an aluminum oxide layer positioned on the bottom dielectric layer; and
a silicon oxide layer positioned on the aluminum oxide layer.

4. The integrated circuit structure of claim 3, wherein the thickness of the aluminum oxide layer is between 1 and 5 angstroms.

5. The integrated circuit structure of claim 3, wherein the thickness of the silicon oxide layer is between 1 and 5 angstroms.

6. The integrated circuit structure of claim 3, wherein the thickness of the silicon oxide layer is substantially the same as that of the aluminum oxide layer.

7. The integrated circuit structure of claim 1, wherein the at least two capping dielectric layers comprise:
a silicon oxide layer positioned on the bottom dielectric layer; and
an aluminum oxide layer positioned on the silicon oxide layer.

8. The integrated circuit structure of claim 7, wherein the thickness of the silicon oxide layer is between 1 and 5 angstroms.

9. The integrated circuit structure of claim 7, wherein the thickness of the aluminum oxide layer is between 1 and 5 angstroms.

10. The integrated circuit structure of claim 7, wherein the thickness of the silicon oxide layer is substantially the same as that of the aluminum oxide layer.

11. The integrated circuit structure of claim 1, wherein the thickness of the bottom dielectric layer is between 40 and 200 angstroms.

12. The integrated circuit structure of claim 1, wherein the bottom dielectric layer and the at least two capping dielectric layers are configured to function as a gate dielectric of a metal-oxide-semiconductor transistor.

13. An integrated circuit structure, comprising:
a bottom electrode;
a bottom dielectric layer positioned on the bottom electrode;
at least two capping dielectric layers positioned on the bottom dielectric layer, wherein one of the two capping dielectric layers is an aluminum oxide layer, and the other is a silicon oxide layer; and
a top electrode positioned on the at least two capping dielectric layers.

14. The integrated circuit structure of claim 13, wherein the bottom dielectric layer comprises a metal oxide layer, and the metal is selected from the group consisting of hafnium, zirconium, and mixtures thereof.

15. The integrated circuit structure of claim 13, wherein the at least two capping dielectric layers comprise:
an aluminum oxide layer positioned on the bottom dielectric layer; and
a silicon oxide layer positioned on the aluminum oxide layer.

16. The integrated circuit structure of claim 15, wherein the thickness of the aluminum oxide layer is between 1 and 5 angstroms.

17. The integrated circuit structure of claim 15, wherein the thickness of the silicon oxide layer is between 1 and 5 angstroms.

18. The integrated circuit structure of claim 15, wherein the thickness of the silicon oxide layer is substantially the same as that of the aluminum oxide layer.

19. The integrated circuit structure of claim 13, wherein the at least two capping dielectric layers comprise:
a silicon oxide layer positioned on the bottom dielectric layer; and
an aluminum oxide layer positioned on the silicon oxide layer.

20. The integrated circuit structure of claim 19, wherein the thickness of the silicon oxide layer is between 1 and 5 angstroms.

21. The integrated circuit structure of claim 19, wherein the thickness of the aluminum oxide layer is between 1 and 5 angstroms.

22. The integrated circuit structure of claim 19, wherein the thickness of the silicon oxide layer is substantially the same as that of the aluminum oxide layer.

23. The integrated circuit structure of claim 13, wherein the thickness of the bottom dielectric layer is between 40 and 200 angstroms.
